(19) United States
(12) Patent Application Publication
(10) Pub. No.: US 2025/0226307 A1
(43) Pub. Date: Jul. 10, 2025

(54) SEMICONDUCTOR DEVICE WITH IMPROVED METAL-FILLING QUALITY OF METAL GATE VIA AND METHOD FOR MANUFACTURING THE SAME

(71) Applicant: TAIWAN SEMICONDUCTOR MANUFACTURING COMPANY, LTD., Hsinchu (TW)

(72) Inventors: Yuting CHENG, Hsinchu (TW); Tzu-Pei CHEN, Hsinchu (TW); Jung-Hao CHANG, Hsinchu (TW); Sung-Li WANG, Hsinchu (TW)

(73) Assignee: TAIWAN SEMICONDUCTOR MANUFACTURING COMPANY, LTD., Hsinchu (TW)

(21) Appl. No.: 18/404,187

(22) Filed: Jan. 4, 2024

(51) Int. Cl. H01L 23/522; H01L 21/768; H01L 21/8234; H01L 23/528; H01L 27/088; H01L 29/06; H01L 29/423; H01L 29/66; H01L 29/775; H01L 29/786

(52) U.S. Cl. CPC H01L 23/5226; H01L 21/76831; H01L 21/76843; H01L 23/5283; H10D 30/014; H10D 30/43; H10D 30/6735; H10D 30/6757; H10D 62/121; H10D 84/0135; H10D 84/0149; H10D 84/038; H10D 84/83

(57) ABSTRACT

A method for manufacturing a semiconductor device includes: forming a semiconductor structure including a metal gate feature; forming an etch stop layer on the semiconductor structure; forming a dielectric layer on the etch stop layer opposite to the semiconductor structure, the etch stop layer being made of a dielectric material different from a dielectric material of the dielectric layer; forming a trench that penetrates the dielectric layer and the etch stop layer so as to expose an upper surface of the metal gate feature; conformally forming a liner material film on the dielectric layer, a trench-defining wall that defines the trench, and the upper surface of the metal gate feature; and forming a via contact material on the liner material film, such that the trench is filled by the liner material film and the via contact material.

### BACKGROUND

With continuous development of semiconductor technology, a continuous reduction in size of various semiconductor devices (for example, such as transistors, diodes, resistors, capacitors, etc.) in an integrated circuit (IC) chip is desired in the semiconductor industry. As the size of a semiconductor device is scaled down, an aspect ratio of a via contact (for example, via to metal gate (VG)) increases due to the smaller size of the via contact, which may cause formation of defects (for example, a void or a seam) in the via contact. The defects in the via contact may adversely affect device performance and production yield of the semiconductor device. Therefore, there is a need to reduce the formation of defects in the via contact.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 6 are schematic views illustrating some intermediate stages of the method as depicted in FIG. 1 in accordance with some embodiments.

FIG. 7 is a schematic view illustrating a semiconductor device in accordance with some embodiments.

FIG. 8A is a schematic view illustrating an intermediate stage of a method for manufacturing the semiconductor device as depicted in FIG. 7 in accordance with some embodiments.

FIG. 8B is a schematic view illustrating an intermediate stage of a method for manufacturing a semiconductor device in accordance with some embodiments.

FIG. 9 is a schematic view illustrating a semiconductor device.

FIGS. 10A and 10B are schematic views illustrating some intermediate stages of a method for manufacturing the semiconductor device as depicted in FIG. 9.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “uppermost,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions.

In recent years, semiconductor devices have been applied in various fields, and application need for the semiconductor devices gradually increases. An integrated circuit (IC) chip may include a plurality of the semiconductor devices, for example, but not limited to, nanosheet field-effect transistors (FETs), forksheet FETs, or FinFETs. In order to meet application need, an increased device functional density (i.e., the number of electrical devices per chip area) of an IC chip is desired, and a reduction in size of each of the semiconductor devices in the IC chip is conducive to increasing the device functional density of the IC chip. However, as the size of a semiconductor device is scaled down, an aspect ratio of each of some elements (for example, metal gate vias) of the semiconductor device increases due to the smaller size of such elements, and some defects (e.g., voids) may be formed in the elements of the semiconductor device during a manufacturing process thereof. For example, when a via contact material for forming a metal gate via of the semiconductor device fills a via hole for forming the metal gate via by a deposition process, the deposition rates of the via contact material on different portions of a hole-defining wall (e.g., a portion constituted by a lateral surface of an etch stop layer made of a dielectric material and another portion constituted by a lateral surface of an interlayer dielectric layer which is disposed on the etch stop layer and which is made of another dielectric material different from the dielectric material of the etch stop layer) that defines the via hole may vary, which may result in an early pinch-off and formation of voids in the metal gate via. These voids may adversely affect electrical characteristics (e.g., an increased resistance) and production quality of the metal gate via.

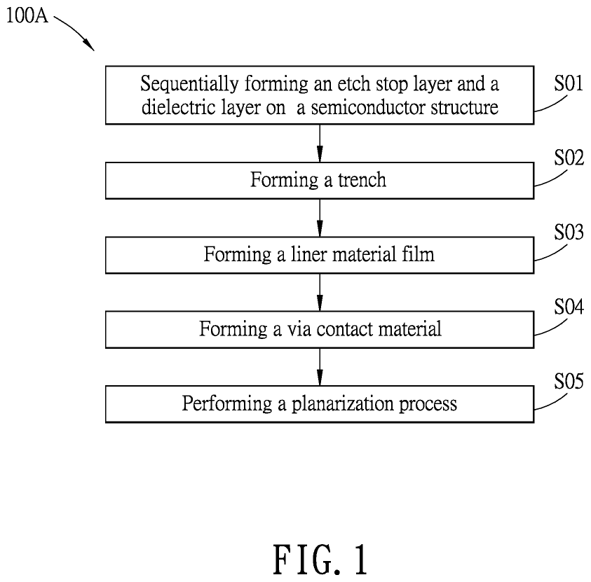

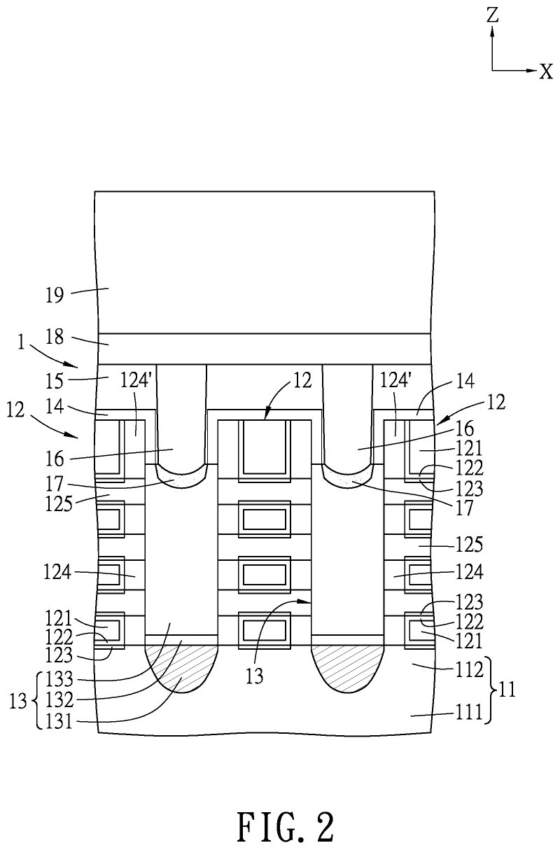

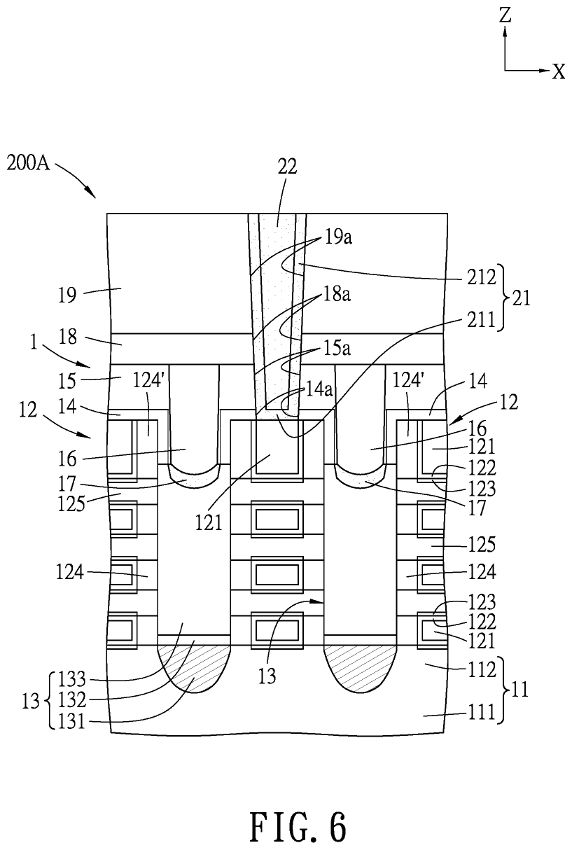

The present disclosure is directed to a semiconductor device and a method for manufacturing the same. FIG. 1 is a flow diagram illustrating a method 100A for manufacturing a semiconductor device 200A shown in FIG. 6 in accordance with some embodiments. FIGS. 2 to 5 illustrate schematic views of some intermediate stages of the method 100A. Some portions may be omitted in FIGS. 2 to 5 for the sake of brevity. Additional steps can be provided before, after or during the method 100A, and some of the steps described herein may be replaced by other steps or be eliminated.

Referring to FIG. 1 and the example illustrated in FIG. 2, the method 100A begins at step S01, where an etch stop layer 18 and a dielectric layer 19 are formed sequentially on a semiconductor structure 1. The semiconductor structure 1 includes a semiconductor substrate 11, a plurality of nanosheet structures 12, a plurality of source/drain features 13, a contact etch stop layer (CESL) 14, a dielectric layer 15, a plurality of conductive vias 16, and a plurality of contact portions 17. In some embodiments, the semiconductor structure 1 is a gate-all-around (GAA) semiconductor structure. Other suitable semiconductor structures for the semiconductor structure 1 are within the contemplated scope of the present disclosure.

The semiconductor substrate 11 may include, for example, but not limited to, an elemental semiconductor or a compound semiconductor. In some embodiments, the elemental semiconductor includes a single species of atoms, such as silicon (Si) or germanium (Ge) in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable materials for the compound semiconductor are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 11 may include a multilayer compound semiconductor structure. In some embodiments, the semiconductor substrate 11 may be a semiconductor on insulator (SOI) (e.g., silicon germanium on insulator (SGOI)). Generally, an SOI substrate includes a layer of a semiconductor material, such as epitaxial silicon (Si), germanium (Ge), silicon germanium, or combinations thereof. The SOI substrate may be doped with a P-type dopant, for example, but not limited to, boron (Br), aluminum (Al), or gallium (Ga). Other suitable P-type dopant materials are within the contemplated scope of the present disclosure. Alternatively, the SOI substrate may be doped with an N-type dopant, for example, but not limited to, nitrogen (N), phosphorus (P), or arsenic (As). Other suitable N-type dopant materials are within the contemplated scope of the present disclosure. In some embodiments, the semiconductor substrate 11 may include a lower portion 111 and an upper portion 112 disposed on the lower portion 111.

The nanosheet structures 12 are disposed on the semiconductor substrate 11 in a Z direction, which is normal to a bottom surface of the semiconductor substrate 11, and are spaced apart from one another in an X direction transverse to the Z direction. In some embodiments, each of the nanosheet structures 12 includes a metal gate feature 121, a plurality of gate dielectric features 122, a plurality of interfacial features 123, a plurality of inner spacers 124, a pair of gate spacers 124′, and a plurality of channel features 125.

The metal gate feature 121 includes an upper gate portion disposed on the channel features 125 and a lower gate portion surrounding the channel features 125. The metal gate feature 121 may include, for example, but not limited to, metal (e.g., tungsten (W)), metal nitride (e.g., titanium nitride (TiN) or tantalum nitride (TaN)), or a combination thereof. Other suitable materials for the metal gate feature 121 are within the contemplated scope of the present disclosure.

The gate dielectric features 122 cover the metal gate feature 121, while exposing an upper surface of the upper gate portion of the metal gate feature 121. In some embodiments, the gate dielectric features 122 may include, for example, but not limited to, silicon oxide, silicon nitride, silicon oxynitride, hafnium oxide, titanium oxide, hafnium zirconium oxide, tantalum oxide, hafnium silicon oxide, zirconium oxide, zirconium silicon oxide, lanthanum oxide, aluminum oxide, yttrium oxide, strontium titanate, barium titanate, barium zirconate, lanthanum silicon oxide, aluminum silicon oxide, hafnium lanthanum oxide, hafnium tantalum oxide, hafnium titanium oxide, or combinations thereof. Other suitable materials for the gate dielectric features 122 are within the contemplated scope of the present disclosure.

An uppermost one of the interfacial features 123 is disposed on a lower surface of an uppermost one of the gate dielectric features 122, and the other ones of the interfacial features 123 are arranged in pairs, where each pair of the interfacial features 123 is disposed at two opposite sides of a corresponding one of the other ones of the gate dielectric features 122 in the Z direction. The interfacial features 123 may include, for example, but not limited to, silicon oxide. Other suitable materials for the interfacial features 123 are within the contemplated scope of the present disclosure.

Each pair of the inner spacers 124 laterally covers a corresponding one of the gate dielectric features 122. The inner spacers 124 may include, for example, but not limited to, silicon oxide, silicon nitride, silicon carbide, silicon oxycarbide, silicon oxynitride, silicon carbonitride, silicon oxycarbonitride, other low dielectric constant (k) materials, or combinations thereof. Other suitable materials for the inner spacers 124 are within the contemplated scope of the present disclosure.

The gate spacers 124′ in each pair respectively cover two opposite lateral surfaces of an uppermost one of the gate dielectric features 122 of a corresponding one of the nanosheet structures 12. In some embodiments, the gate spacers 124′ and the inner spacers 124 are separately formed. In some embodiments, the gate spacers 124′ are formed before the inner spacers 124 are formed.

Each of the channel features 125 is disposed between two adjacent ones of the interfacial features 123. The channel features 125 are formed from semiconductor nanosheets, which may be, for example, but not limited to, silicon (Si) nanosheets. Other suitable semiconductor nanosheets for forming the channel features 125 are within the contemplated scope of the present disclosure. The channel features 125 collectively form a channel region disposed between two corresponding ones of the source/drain features 13.

The source/drain features 13 and the nanosheet structures 12 are alternated with each other in the X direction. Each of the source/drain features 13 may include a first layer 131, a second layer 132, and a third layer 133. The first layer 131 is disposed in the upper portion 112 of the semiconductor substrate 11. The first layer 131 may be made of a semiconductor material, for example, but not limited to, silicon (Si). Other suitable semiconductor materials for the first layer 131 are within the contemplated scope of the present disclosure. The second layer 132 is disposed on the first layer 131 opposite to the upper portion 112 of the semiconductor substrate 11. The second layer 132 may be made of a dielectric material, for example, but not limited to, silicon oxide or silicon nitride. Other suitable dielectric materials for the second layer 132 are within the contemplated scope of the present disclosure. In some embodiments, the second layer 132 may be referred to as a bottom dielectric isolation (BDI). The third layer 133 is disposed on the second layer 132 opposite to the first layer 131. The third layer 133 may be made of silicon (Si) or silicon germanium. Other suitable materials for the third layer 133 are within the contemplated scope of the present disclosure.

The contact etch stop layer 14 is conformally formed to cover the metal gate feature 121 of each of the nanosheet structures 12, the uppermost one of the gate dielectric features 122 of each of the nanosheet structures 12, and the gate spacers 124′ of each of the nanosheet structures 12. The contact etch stop layer 14 may include, for example, but not limited to, silicon oxide, silicon nitride, silicon oxynitride, or combinations thereof. Other suitable materials for the contact etch stop layer 14 are within the contemplated scope of the present disclosure.

The dielectric layer 15 is disposed on the contact etch stop layer 14 opposite to the semiconductor substrate 11. The dielectric layer 15 may include, for example, but not limited to, silicon oxide, silicon nitride, silicon carbide, silicon oxycarbide, silicon oxynitride, silicon carbonitride, silicon oxycarbonitride, other low dielectric constant (k) materials, or combinations thereof. Other suitable materials for the dielectric layer 15 are within the contemplated scope of the present disclosure.

The conductive vias 16 are disposed in the dielectric layer 15, and penetrate the contact etch stop layer 14. The conductive vias 16 are electrically connected to the source/drain features 13, respectively. The conductive vias 16 may be made of a conductive material, for example, but not limited to, tungsten (W), ruthenium (Ru), cobalt (Co), copper (Cu), molybdenum (Mo), or combinations thereof. Other suitable conductive materials for the conductive vias 16 are within the contemplated scope of the present disclosure.

In some embodiments, the semiconductor structure 1 may further include a glue layer (not shown) covering lateral and bottom surfaces of each of the conductive vias 16. The glue layer may include, for example, but not limited to, tantalum nitride, titanium nitride, or a combination thereof. Other suitable materials for the glue layer are within the contemplated scope of the present disclosure.

Each of the contact portions 17 is disposed between the third layer 133 of a corresponding one of the source/drain features 13 and a corresponding one of the conductive vias 16, so that the corresponding one of the source/drain features 13 can be electrically connected to the corresponding one of the conductive vias 16 therethrough. Each of the contact portions 17 may be a metal silicide, for example, but not limited to, titanium silicide, tantalum silicide, cobalt silicide, or combinations thereof. Other suitable materials for the contact portions 17 are within the contemplated scope of the present disclosure.

The etch stop layer 18 is formed on the dielectric layer 15 and the conductive vias 16 by a suitable deposition process, for example, but not limited to, chemical vapor deposition (CVD), atomic layer deposition (ALD), or other suitable deposition processes. The etch stop layer 18 may include, for example, but not limited to, lanthanum oxide, aluminum oxide, yttrium oxide, tantalum carbonitride, zirconium silicide, silicon carbon oxynitride, silicon oxycarbide, silicon carbonitride, zirconium nitride, zirconium aluminum oxide, titanium oxide, tantalum oxide, zirconium oxide, hafnium oxide, silicon nitride, hafnium silicide, aluminum oxynitride, silicon oxide, silicon carbide, zinc oxide, or combinations thereof. Other suitable materials for the etch stop layer 18 are within the contemplated scope of the present disclosure. In some embodiments, the etch stop layer 18 and the contact etch stop layer 14 may have different thicknesses. In some embodiments, the thickness of the contact etch stop layer 14 is smaller than that of the etch stop layer 18.

The dielectric layer 19 is formed on the etch stop layer 18 opposite to the first dielectric layer 15 by a suitable deposition process, for example, but not limited to, CVD, ALD, or other suitable deposition processes. The material for the dielectric layer 19 may be the same as or similar to that of the dielectric layer 15, and thus details thereof are omitted for the sake of brevity. In some embodiments, the dielectric layer 19 is made of a material different from that of the etch stop layer 18.

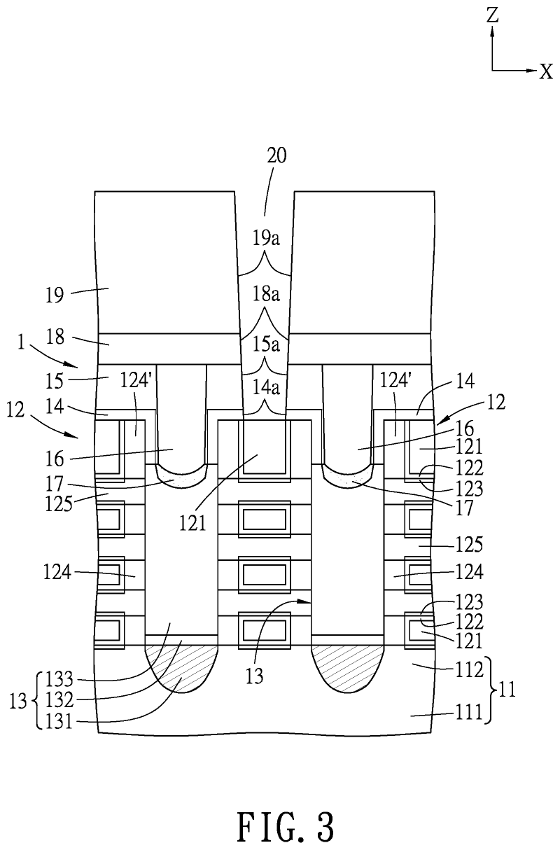

Referring to FIG. 1 and the example illustrated in FIG. 3, the method 100A then proceeds to step S02, where a patterning process is performed to form at least one trench 20 and to expose the metal gate feature 121 of a corresponding one of the nanosheet structures 12. The trench 20 may be defined by a trench-defining wall constituted by a lateral surface 19a of the dielectric layer 19, a lateral surface 18a of the etch stop layer 18, a lateral surface 15a of the dielectric layer 15, and a lateral surface 14a of the contact etch stop layer 14. Step S02 may include sub-step (i) forming a patterned mask (not shown) on the dielectric layer 19 to partially expose the dielectric layer 19, sub-step (ii) performing an etching process to etch a portion of the dielectric layer 19, a portion of the etch stop layer 18, a portion of the dielectric layer 15, and a portion of the contact etch stop layer 14 through the patterned mask to form the trench 20, and sub-step (iii) removing the patterned mask by a suitable removal process (e.g., an ashing process or other suitable removal processes). In sub-step (i), the patterned mask may include a photoresist material or other suitable mask materials, and may be formed by coating a photoresist layer, soft-baking the photoresist layer, exposing the photoresist layer through a photomask, post-exposure baking the photoresist layer, and developing the photoresist layer, followed by hard-baking the photoresist layer, so as to obtain the patterned mask. In sub-step (ii), the etching process may be a dry etching process, a wet etching process, or a combination thereof. In some embodiments, the trench 20 may have an aspect ratio ranging from about 3 to about 8. In some embodiments, the trench 20 may have a bottom portion that has a critical dimension that ranges from about 1 nm to about 15 nm. In some embodiments, the critical dimension of the bottom portion of the trench 20 is substantially the same as a critical dimension of an upper surface of the upper gate portion of the metal gate feature 121 of a corresponding one of the nanosheet structures 12. In some alternative embodiments, the critical dimension of the bottom portion of the trench 20 is smaller than the critical dimension of the upper surface of the upper gate portion of the metal gate feature 121 of the corresponding one of the nanosheet structures 12. In some embodiments, the trench 20 may further extend into the upper gate portion of the metal gate feature 121 of the corresponding one of the nanosheet structures 12.

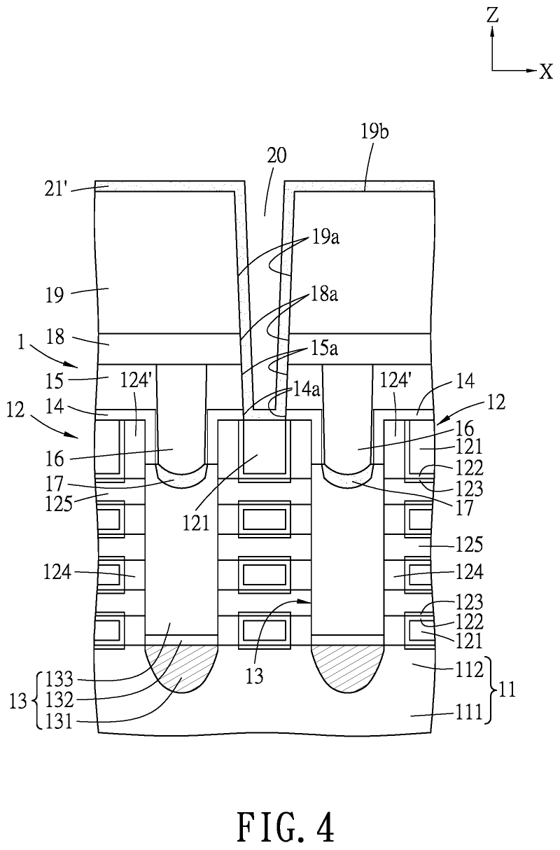

Referring to FIG. 1 and the example illustrated in FIG. 4, the method 100A then proceeds to step S03, where a liner material film 21′ is conformally formed on the structure shown in FIG. 3 to cover an upper surface 19b of the dielectric layer 19, the lateral surface 19a of the dielectric layer 19, the lateral surface 18a of the etch stop layer 18, the lateral surface 15a of the dielectric layer 15, the lateral surface 14a of the contact etch stop layer 14, and the upper surface of the upper gate portion of the metal gate feature 121. Step S03 may be performed by a suitable deposition process, for example, but not limited to, CVD, physical vapor deposition (PVD), ALD, or other suitable deposition processes. The liner material film 21′ may be made of a metal (e.g., ruthenium (Ru), tungsten (W), cobalt (Co), copper (Cu), molybdenum (Mo), or titanium (Ti)), a metal compound (e.g., titanium nitride, titanium oxide or tantalum nitride), or a combination thereof. Other suitable materials for the liner material film 21′ are within the contemplated scope of the present disclosure. In some embodiments, the liner material film 21′ may have a thickness ranging from about 1 Å to about 30 Å.

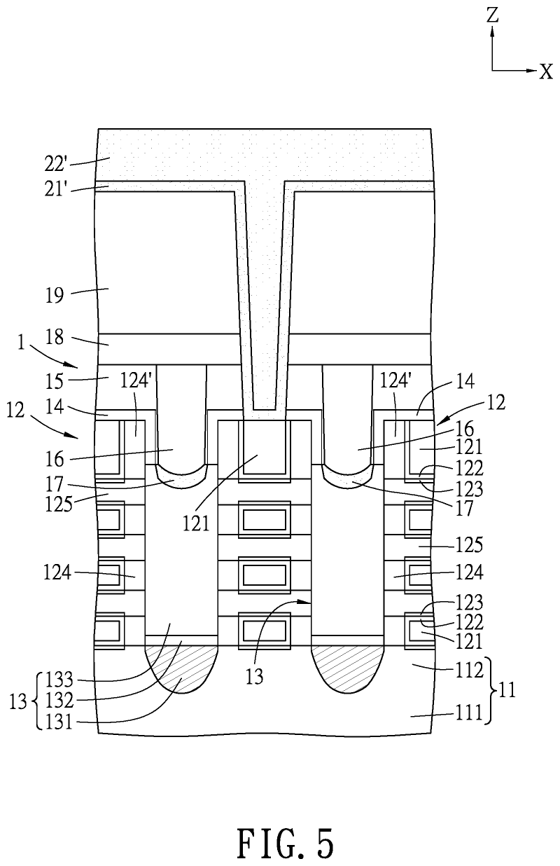

Referring to FIG. 1 and the example illustrated in FIG. 5, the method 100A then proceeds to step S04, where a via contact material 22′ is formed on the structure shown in FIG. 4 and fully fills the trench 20 of the structure shown in FIG. 4. Step S04 may be performed by a suitable deposition process, for example, but not limited to, CVD, PVD, ALD, or other suitable deposition processes. The via contact material 22′ may include, for example, but not limited to, tungsten (W), ruthenium (Ru), cobalt (Co), copper (Cu), molybdenum (Mo), or combinations thereof. Other suitable materials for the via contact material 22′ are within the contemplated scope of the present disclosure. A deposition rate of the via contact material 22′ on the liner material film 21′ is substantially identical. Therefore, the via contact material 22′ can fully fill the trench 20 of the structure shown in FIG. 4. In some embodiments, the via contact material 22′ may be the same as the material for forming the liner material film 21′. In some embodiments, the via contact material 22′ and the liner material film 21′ are formed by different deposition processes.

Referring to FIG. 1 and the example illustrated in FIG. 6, the method 100A then proceeds to step S05, where a planarization process is performed to remove an excess portion of the via contact material 22′ and an excess portion of the liner material film 21′ on the dielectric layer 19, so as to obtain the semiconductor device 200A. In some embodiments, an upper portion of the dielectric layer 19 may also be removed by the planarization process. In this step, the planarization process may be a chemical mechanical polishing (CMP) process or other suitable planarization processes. After this step, the liner material film 21′ is formed into a liner 21, and the via contact material 22′ is formed into a via contact 22, where a lateral surface and a bottom surface of the via contact 22 are covered by the liner 21. In some embodiments, the via contact 22 may be referred to as a deep via contact. In some embodiments, the lateral surface 19a of the dielectric layer 19, the lateral surface 18a of the etch stop layer 18, the lateral surface 15a of the dielectric layer 15, and the lateral surface 14a of the contact etch stop layer 14 are covered by the liner 121. In some embodiments, the liner 21 and the via contact 22 may be made of the same material. In some embodiments, an interface exists between the liner 21 and the via contact 22. The via contact 22 cooperates with the liner 21 to serve as a metal gate via that passes through the dielectric layer 19, the etch stop layer 18, the dielectric layer 15 and the contact etch stop layer 14 so that the metal gate via is connected to the upper gate portion of the metal gate feature 121 of the corresponding one of the nanosheet structures 12. The metal gate via may sometimes be referred to as a via gate or a via to metal gate, both of which may be abbreviated as “VG.” In some embodiments, the metal gate via has an aspect ratio ranging from about 3 to about 8. In some embodiments, a lower surface of the metal gate via has a size ranging from about 1 nm to about 15 nm. In some embodiments, the size of the lower surface of the metal gate via is substantially the same as that of the upper surface of the upper gate portion of the metal gate feature 121 of the corresponding one of the nanosheet structures 12. In some alternative embodiments, the size of the lower surface of the metal gate via is smaller than that of the upper surface of the upper gate portion of the metal gate feature 121 of the corresponding one of the nanosheet structures 12.

In some embodiments, the liner 21 may be divided into a lower liner portion 211 and an upper liner portion 212 extending upwardly in the Z direction from the lower liner portion 211. The lower liner portion 211 is disposed on the upper gate portion of the metal gate feature 121 of a corresponding one of the nanosheet structures 12. The upper liner portion 212 is disposed on the trench-defining wall of the trench 20 (see FIG. 3) to cover the lateral surface 19a of the dielectric layer 19, the lateral surface 18a of the etch stop layer 18, the lateral surface 15a of the dielectric layer 15, and the lateral surface 14a of the contact etch stop layer 14. In some embodiments, each of the lower liner portion 211 and the upper liner portion 212 may have a thickness ranging from about 1 Å to about 30 Å (i.e., the thickness of the liner material film 21′). When the thickness of the lower liner portion 211 is greater than about 30 Å, a contact resistance between the via contact 22 and the metal gate feature 121 of the corresponding one of the nanosheet structures 12 may increase, which may adversely affect device performance of the semiconductor device 200A. When the thickness of the upper liner portion 212 is less than about 1 Å, a deposition rate of the via contact material 22′ may be adversely affected, which may result in formation of some defects (e.g., voids) in the via contact 22 thus formed. When the thickness of the upper liner portion 212 is greater than about 30 Å, the via contact material 22′ may not efficiently and fully fill the trench 20, which is not conducive for formation of the via contact 22. In some embodiments, the percentage of an area of the trench-defining wall of the trench 20 covered by the upper liner portion 212 based on a total surface area of the trench-defining wall may be greater than about 0% and may be up to about 100%.

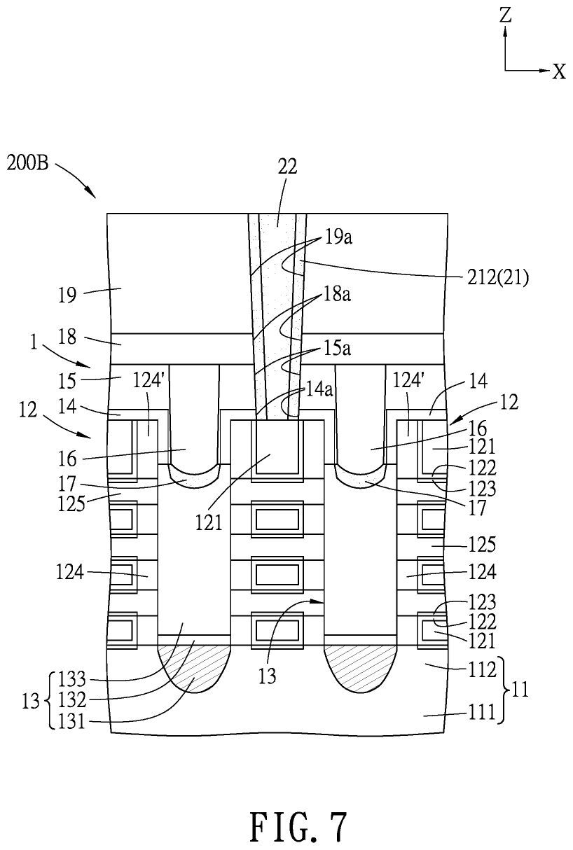

FIG. 7 illustrates a schematic view of a semiconductor device 200B in accordance with some embodiments. The semiconductor device 200B is similar to the semiconductor device 200A except that, the liner 21 only includes the upper liner portion 212 and does not include the lower liner portion 211, such that the via contact 22 is in direct contact with the upper gate portion of the metal gate feature 121 of the corresponding one of the nanosheet structures 12. The via contact 22 may be referred to as a deep via contact, and passes through the dielectric layer 19, the etch stop layer 18, the dielectric layer 15, and the contact etch stop layer 14 so as to be connected to the metal gate feature 121 of a corresponding one of the nanosheet structures 12.

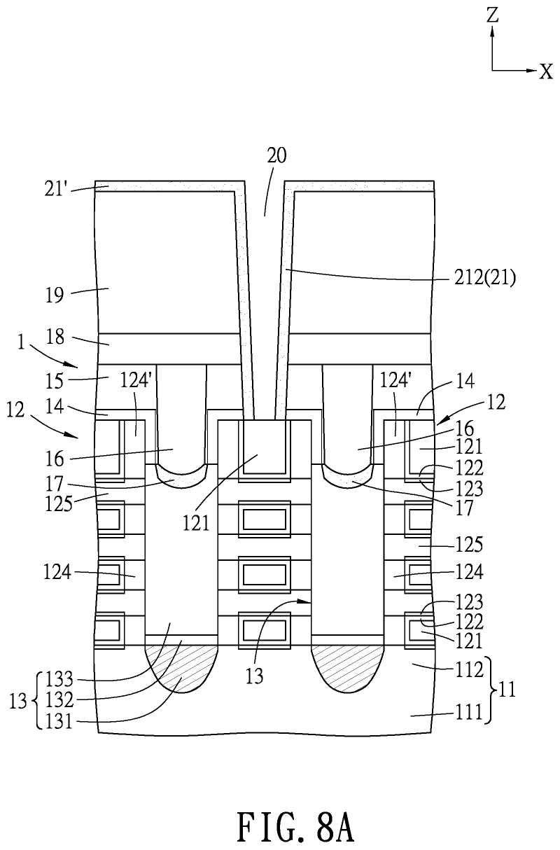

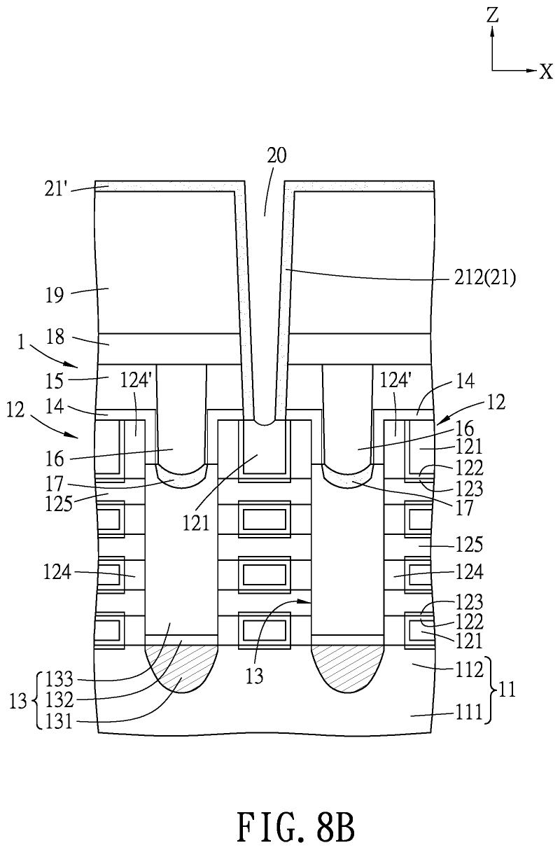

Referring to FIGS. 4, 8A and 8B, the semiconductor device 200B may be made using a method similar to the method 100A except that, after step S03 and before step S04, a portion of the liner material film 21′ in contact with the metal gate feature 121 of the corresponding one of the nanosheet structures 12 is removed. In some embodiments, the portion of the liner material film 21′ may be removed by a suitable etching process, for example, but not limited to, a dry etching process or other suitable etching processes. In some embodiments, the dry etching process may be a plasma etching process. In some embodiments, the plasma etching process may be performed using a gas, for example, but not limited to, argon (Ar) gas, helium (He) gas, titanium chloride (TiCl₄) gas, hydrogen (H₂) gas, neon (Ne) gas, boron trichloride (BCl₃) gas, chlorine (Cl₂) gas, nitrogen (N₂) gas, oxygen (O₂) gas, hexafluorobutadiene (C₄F₆) gas, octafluorocyclobutane (C₄F₈) gas, carbon tetrafluoride (CF₄) gas, fluoromethane (CH₃F) gas, trifluoromethane (CHF₃) gas, sulfur hexafluoride (SF₆) gas, sulfur dioxide (SO₂) gas, other suitable gases, or combinations thereof. In some embodiments, the gas flow rate of the gas used in the plasma etching process may range from about 5 standard cubic centimeters per cubic (sccm) to about 1000 sccm. In some embodiments, the plasma generation power used in the plasma etching process may range from about 1 W to about 2000 W. In some embodiments, the plasma etching process may be performed at a temperature ranging from about 0° C. to about 400° C. After removal of the portion of the liner material film 21′ (see FIG. 8A), steps S04 and S05 may be sequentially performed, so as to obtain the semiconductor device 200B. In the semiconductor device 200B, by having the upper liner portion 212 of the liner 21 to cover the lateral surface 19a of the dielectric layer 19, the lateral surface 18a of the etch stop layer 18, the lateral surface 15a of the dielectric layer 15, and the lateral surface 14a of the contact etch stop layer 14, the deposition rate of the via contact material 22′ on the liner material film 21′ is substantially identical, and formation of defects (e.g., voids) in the via contact 22 thus formed may be avoided, and a contact resistance between the via contact 22 and the metal gate feature 121 of a corresponding one of the nanosheet structures 12 may be reduced because the via contact 22 is in direct contact with the metal gate feature 121 of the corresponding one of the nanosheet structures 12. In some embodiments, after removal of the portion of the liner material film 21′, the upper gate portion of the metal gate feature 121 of the corresponding one of the nanosheet structures 12 may be slightly recessed caused by overetching (see FIG. 8B). In some embodiments, the upper liner portion 212 (or the liner 21) of the semiconductor device 200B includes an upper part and a lower part connected between the upper part and the metal gate feature 121 of the corresponding one of the nanosheet structures 12, and the upper part of the upper liner portion 212 (or the liner 21) has a thickness different from that of the lower part of the upper liner portion 212 (or the liner 21). For example, the thickness of the upper part of the upper liner portion 212 (or the liner 21) is smaller or larger than that of the lower part of the upper liner portion 212 (or the liner 21). The plasma etching process to remove the portion of the liner material film 21′ in contact with the metal gate feature 121 of the corresponding one of the nanosheet structures 12 may result in different thicknesses of the upper and lower parts of the upper liner portion 212.

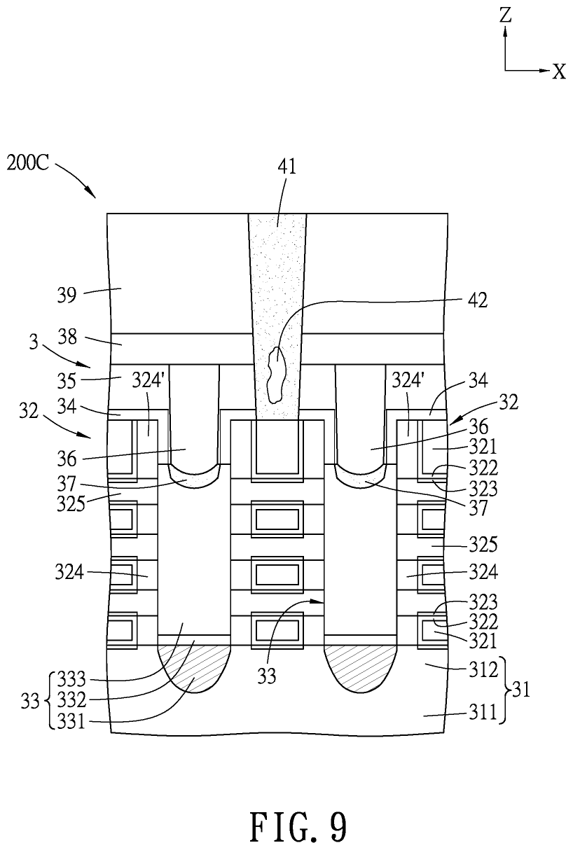

FIG. 9 illustrates a schematic view of a semiconductor device 200C. The semiconductor device 200C includes a semiconductor structure 3, an etch stop layer 38, a dielectric layer 39, and a via contact 41. The semiconductor device 200C may be manufactured using a method similar to the method 100A, except that step S03 (i.e., formation of the liner material film 21′ shown in FIG. 4) of the method 100A is not performed.

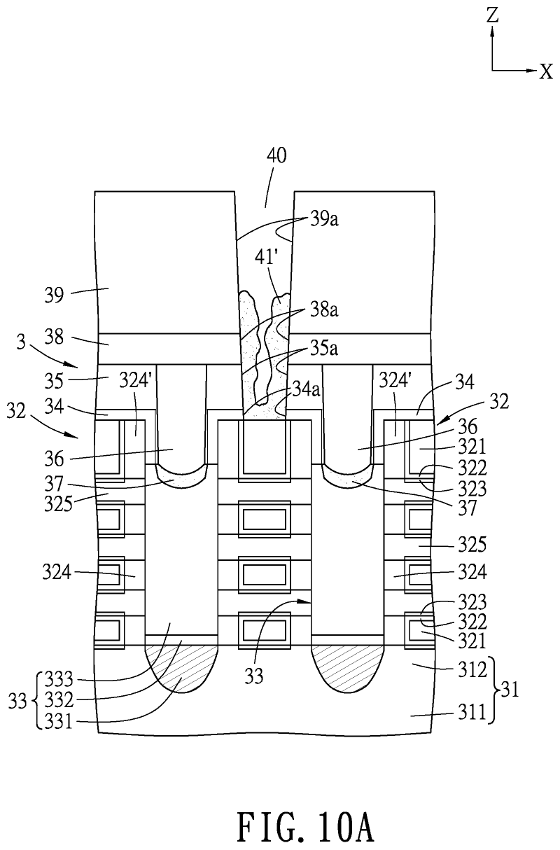

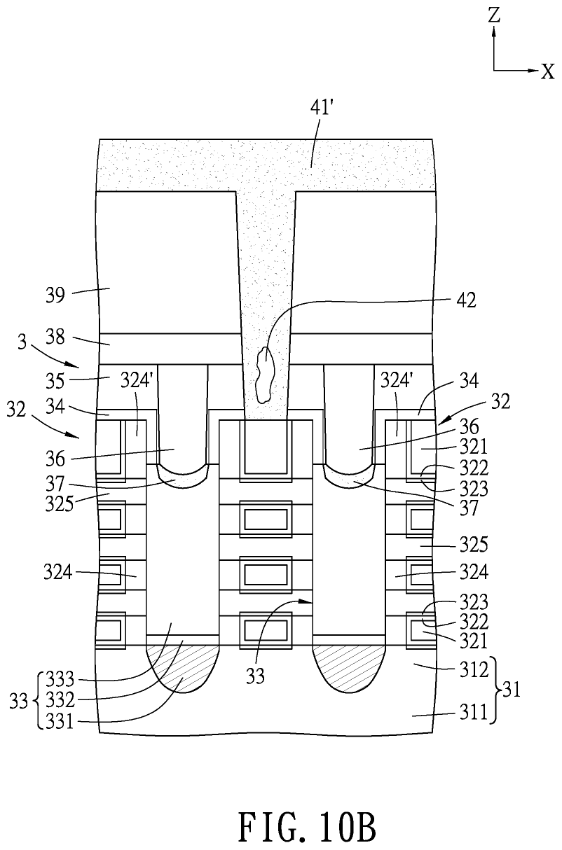

FIGS. 10A and 10B illustrate an intermediate step of a method for manufacturing the semiconductor device 200C, which is similar to step S04 of the method 100A.

As shown in FIG. 10A, a via contact material 41′ is initially formed to partially fill a trench 40 that is formed to penetrate the dielectric layer 39 and the etch stop layer 38 and to extend into the semiconductor structure 3. The semiconductor structure 3 is the same as the semiconductor structure 1 as described in step S01 of the method 100A. The semiconductor structure 3 includes a semiconductor substrate 31, a plurality of nanosheet structures 32, a plurality of source/drain features 33, a contact etch stop layer 34, a dielectric layer 35, a plurality of conductive vias 36, and a plurality of contact portions 37. Each of the nanosheet structures 32 includes a metal gate feature 321, a plurality of gate dielectric features 322, a plurality of interfacial features 323, a plurality of inner spacers 324, a pair of gate spacers 324′, and a plurality of channel features 325. Each of the source/drain features 33 includes a first layer 331, a second layer 332, and a third layer 333. The trench 40 is formed to penetrate the dielectric layer 39, the etch stop layer 38, the dielectric layer 35, and the contact etch stop layer 34, so as to expose an upper surface of the metal gate feature 321 of a corresponding one of the nanosheet structures 32. In some embodiments, the trench 40 may be defined by a trench-defining wall constituted by a lateral surface 34a of the contact etch stop layer 34, a lateral surface 35a of the dielectric layer 35, a lateral surface 38a of the etch stop layer 38, and a lateral surface 39a of the dielectric layer 39. The material and process for forming the via contact material 41′ may be the same as or similar to those for forming the via contact material 22′ as described in step S04 of the method 100A, and thus details thereof are omitted for the sake of brevity. As shown in FIG. 10B, the via contact material 41′ is formed in the trench 40 (see FIG. 10A) and on an upper surface of the dielectric layer 39. After formation of the via contact material 41′, a planarization process (e.g., CMP or other suitable planarization processes) is conducted on the structure shown in FIG. 10B to remove an excess portion of the via contact material 41′ on the dielectric layer 39, so as to obtain the semiconductor device 200C as shown in FIG. 9. In some embodiments, an upper portion of the dielectric layer 39 may also be removed by the planarization process. It is noted that, in the semiconductor device 200C, a void 42 is formed in the via contact 41 (a remaining portion of the via contact material 41′ after the planarization process) when the etch stop layer 38 is made of a material different from a material of the dielectric layer 35 and/or a material of the dielectric layer 39. The void 42 may be formed because of variations in a deposition rate of the via contact material 41′ on the trench-defining wall that defines the trench 40. For example, the deposition rate of the via contact material 41′ on the lateral surface 38a of the etch stop layer 38 (e.g., made of silicon nitride) may be faster than the deposition rate of the via contact material 41′ on the lateral surface 35a of the dielectric layer 35 (e.g., made of silicon oxide) or the lateral surface 39a of the dielectric layer 39 (e.g., made of silicon oxide), causing an early pinch-off phenomenon, resulting in incomplete filling of the via contact material 41′ in the trench 40 and formation of the void 42. In this case, the void 42 may cause an increased resistance of the via contact 41, which may adversely affect device performance of the semiconductor device 200C.

In comparison with the semiconductor device 200C, in a manufacturing process of the semiconductor device 200A (or the semiconductor device 200B), there may not exist any void in the via contact 22 (see FIG. 6) because a deposition rate of the via contact material 22′ on the liner material film 21′ is identical and the via contact material 22′ can completely fill the trench 20 (see FIGS. 4 and 5).

In a process for manufacturing a semiconductor device of this disclosure, before forming a via contact in a trench, a liner material film is deposited on a trench-defining wall that defines the trench, so that a via contact material for forming the via contact may completely fill the trench due to an identical deposition rate of the via contact material on the liner material film, and formation of defects (e.g., voids) in the via contact may be avoided, which is conducive to increasing device performance and production yield of the semiconductor device.

In accordance with some embodiments of the present disclosure, a method for manufacturing a semiconductor device includes: forming a semiconductor structure including a metal gate feature; forming an etch stop layer on the semiconductor structure; forming a first dielectric layer on the etch stop layer opposite to the semiconductor structure, the etch stop layer being made of a dielectric material different from a dielectric material of the first dielectric layer; forming a trench that penetrates the first dielectric layer and the etch stop layer so as to expose an upper surface of the metal gate feature; conformally forming a liner material film on the first dielectric layer, a trench-defining wall that defines the trench, and the upper surface of the metal gate feature; and forming a via contact material on the liner material film, such that the trench is filled by the liner material film and the via contact material.

In accordance with some embodiments of the present disclosure, the semiconductor structure further includes a second dielectric layer which is disposed below the etch stop layer opposite to the first dielectric layer and which is made of a dielectric material different from the dielectric material of the etch stop layer. The trench further penetrates the second dielectric layer.

In accordance with some embodiments of the present disclosure, the method for manufacturing a semiconductor device further includes, after formation of the liner material film and before formation of the via contact material, removing a portion of the liner material film in contact with the upper surface of the metal gate feature, so as to expose the upper surface of the metal gate feature.

In accordance with some embodiments of the present disclosure, the portion of the liner material film is removed by a plasma etching process.

In accordance with some embodiments of the present disclosure, the plasma etching process is conducted using a gas that includes argon gas, helium gas, hydrogen gas, neon gas, titanium chloride gas, boron trichloride gas, chlorine gas, nitrogen gas, oxygen gas, hexafluorobutadiene gas, octafluorocyclobutane gas, carbon tetrafluoride gas, fluoromethane gas, trifluoromethane gas, sulfur hexafluoride gas, sulfur dioxide gas, or combinations thereof.

In accordance with some embodiments of the present disclosure, a gas flow rate of the gas used in the plasma etching process ranges from about 5 sccm to about 1000 sccm, and a plasma generation power used in the plasma etching process ranges from about 1 W to about 2000 W.

In accordance with some embodiments of the present disclosure, after removal of the portion of the liner material film, a portion of the liner material film remains to cover the trench-defining wall and includes an upper part and a lower part that is connected between the upper part and the metal gate feature. The upper part has a thickness smaller than a thickness of the lower part.

In accordance with some embodiments of the present disclosure, the method for manufacturing a semiconductor device further includes, after formation of the via contact material, conducting a planarization process to remove an excess portion of the via contact material and an excess portion of the liner material film, so as to form the via contact material into a via contact and to form the liner material film into a liner.

In accordance with some embodiments of the present disclosure, a percentage of an area of the trench-defining wall of the trench covered by the liner based on a total surface area of the trench-defining wall is greater than about 0% and up to about 100%.

In accordance with some embodiments of the present disclosure, a method for manufacturing a semiconductor device includes: forming a semiconductor structure including a metal gate feature and a first dielectric layer covering the metal gate feature, forming an etch stop layer on the first dielectric layer; forming a second dielectric layer on the etch stop layer opposite to the first dielectric layer, the etch stop layer being made of a dielectric material different from a dielectric material of the first dielectric layer or a dielectric material of the second dielectric layer; forming a trench that penetrates the second dielectric layer, the etch stop layer, and the first dielectric layer so as to expose an upper surface of the metal gate feature; and forming a metal gate via in the trench so as to be connected to the metal gate feature, the metal gate via including a liner and a via contact covered by the liner.

In accordance with some embodiments of the present disclosure, formation of the metal gate via includes: conformally forming a liner material film on the second dielectric layer, a trench-defining wall that defines the trench, and the upper surface of the metal gate feature; forming a via contact material on the liner material film and in the trench, such that the trench is filled by the via contact material; and removing an excess portion of the via contact material and an excess portion of the liner material film, so as to obtain the metal gate via.

In accordance with some embodiments of the present disclosure, after removal of the excess portion of the via contact material and the excess portion of the liner material film, the via contact material is formed into the via contact, and the liner material film is formed into the liner. The liner includes a lower liner portion and an upper liner portion extending upwardly from the lower liner portion. The lower liner portion is disposed between the via contact and the upper surface of the metal gate feature. The upper liner portion laterally covers the via contact.

In accordance with some embodiments of the present disclosure, the method for manufacturing a semiconductor device further includes, after formation of the liner material film and before formation of the via contact material, removing a portion of the liner material film in contact with the upper surface of the metal gate feature.

In accordance with some embodiments of the present disclosure, after removal of the excess portion of the via contact material and the excess portion of the liner material film, the via contact material is formed into the via contact, and the liner material film is formed into the liner. The via contact is in direct contact with the metal gate feature and is laterally covered by the liner.

In accordance with some embodiments of the present disclosure, the trench is formed to further extend into an upper gate portion of the metal gate feature.

In accordance with some embodiments of the present disclosure, a semiconductor device includes a semiconductor structure, an etch stop layer, a second dielectric layer, and a metal gate via. The semiconductor structure includes a metal gate feature and a first dielectric layer disposed on the metal gate feature. The etch stop layer is disposed on the first dielectric layer opposite to the metal gate feature. The second dielectric layer is disposed on the etch stop layer opposite to the first dielectric layer. The metal gate via is disposed in the second dielectric layer, the etch stop layer and the first dielectric layer, and is connected to the metal gate feature. The metal gate via includes a liner and a via contact covered by the liner.

In accordance with some embodiments of the present disclosure, the liner includes a lower liner portion disposed on the metal gate feature and covering a bottom surface of the via contact, and an upper liner portion extending upwardly from the lower liner portion and covering a lateral surface of the via contact.

In accordance with some embodiments of the present disclosure, the liner covers a lateral surface of the via contact, and the via contact is in direct contact with the metal gate feature.

In accordance with some embodiments of the present disclosure, the liner and the via contact are made of a same material.

In accordance with some embodiments of the present disclosure, an upper surface of the metal gate feature has a size ranging from about 1 nm to about 15 nm.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a semiconductor structure including a metal gate feature;
forming an etch stop layer on the semiconductor structure;
forming a first dielectric layer on the etch stop layer opposite to the semiconductor structure, the etch stop layer being made of a dielectric material different from a dielectric material of the first dielectric layer;
forming a trench that penetrates the first dielectric layer and the etch stop layer so as to expose an upper surface of the metal gate feature;
conformally forming a liner material film on the first dielectric layer, a trench-defining wall that defines the trench, and the upper surface of the metal gate feature; and
forming a via contact material on the liner material film, such that the trench is filled by the liner material film and the via contact material.

2. The method as claimed in claim 1, wherein
the semiconductor structure further includes a second dielectric layer which is disposed below the etch stop layer opposite to the first dielectric layer and which is made of a dielectric material different from the dielectric material of the etch stop layer; and
the trench further penetrates the second dielectric layer.

3. The method as claimed in claim 1, further comprising, after formation of the liner material film and before formation of the via contact material, removing a portion of the liner material film in contact with the upper surface of the metal gate feature, so as to expose the upper surface of the metal gate feature.

4. The method as claimed in claim 3, wherein the portion of the liner material film is removed by a plasma etching process.

5. The method as claimed in claim 4, wherein the plasma etching process is conducted using a gas that includes argon gas, helium gas, hydrogen gas, neon gas, titanium chloride gas, boron trichloride gas, chlorine gas, nitrogen gas, oxygen gas, hexafluorobutadiene gas, octafluorocyclobutane gas, carbon tetrafluoride gas, fluoromethane gas, trifluoromethane gas, sulfur hexafluoride gas, sulfur dioxide gas, or combinations thereof.

6. The method as claimed in claim 5, wherein a gas flow rate of the gas used in the plasma etching process ranges from 5 sccm to 1000 sccm, and a plasma generation power used in the plasma etching process ranges from 1 W to 2000 W.

7. The method as claimed in claim 4, wherein, after removal of the portion of the liner material film, a portion of the liner material film remains to cover the trench-defining wall and includes an upper part and a lower part that is connected between the upper part and the metal gate feature, the upper part having a thickness smaller than a thickness of the lower part.

8. The method as claimed in claim 1, further comprising, after formation of the via contact material, conducting a planarization process to remove an excess portion of the via contact material and an excess portion of the liner material film, so as to form the via contact material into a via contact and to form the liner material film into a liner.

9. The method as claimed in claim 8, wherein a percentage of an area of the trench-defining wall of the trench covered by the liner based on a total surface area of the trench-defining wall is greater than 0% and up to 100%.

10. A method for manufacturing a semiconductor device, comprising:
forming a semiconductor structure including a metal gate feature and a first dielectric layer covering the metal gate feature;
forming an etch stop layer on the first dielectric layer;
forming a second dielectric layer on the etch stop layer opposite to the first dielectric layer, the etch stop layer being made of a dielectric material different from a dielectric material of the first dielectric layer or a dielectric material of the second dielectric layer;
forming a trench that penetrates the second dielectric layer, the etch stop layer, and the first dielectric layer so as to expose an upper surface of the metal gate feature; and
forming a metal gate via in the trench so as to be connected to the metal gate feature, the metal gate via including a liner and a via contact covered by the liner.

11. The method as claimed in claim 10, wherein formation of the metal gate via includes:
conformally forming a liner material film on the second dielectric layer, a trench-defining wall that defines the trench, and the upper surface of the metal gate feature;
forming a via contact material on the liner material film and in the trench, such that the trench is filled by the via contact material; and
removing an excess portion of the via contact material and an excess portion of the liner material film, so as to obtain the metal gate via.

12. The method as claimed in claim 11, wherein after removal of the excess portion of the via contact material and the excess portion of the liner material film, the via contact material is formed into the via contact, and the liner material film is formed into the liner, the liner including a lower liner portion and an upper liner portion extending upwardly from the lower liner portion, the lower liner portion being disposed between the via contact and the upper surface of the metal gate feature, the upper liner portion laterally covering the via contact.

13. The method as claimed in claim 11, further comprising, after formation of the liner material film and before formation of the via contact material, removing a portion of the liner material film in contact with the upper surface of the metal gate feature.

14. The method as claimed in claim 13, wherein after removal of the excess portion of the via contact material and the excess portion of the liner material film, the via contact material is formed into the via contact, and the liner material film is formed into the liner, the via contact being in direct contact with the metal gate feature and being laterally covered by the liner.

15. The method as claimed in claim 13, wherein the trench is formed to further extend into an upper gate portion of the metal gate feature.

16. A semiconductor device, comprising:
a semiconductor structure including a metal gate feature and a first dielectric layer disposed on the metal gate feature;
an etch stop layer disposed on the first dielectric layer opposite to the metal gate feature;
a second dielectric layer disposed on the etch stop layer opposite to the first dielectric layer; and
a metal gate via disposed in the second dielectric layer, the etch stop layer and the first dielectric layer, and connected to the metal gate feature, the metal gate via including a liner and a via contact covered by the liner.

17. The semiconductor device as claimed in claim 16, wherein the liner includes a lower liner portion disposed on the metal gate feature and covering a bottom surface of the via contact, and an upper liner portion extending upwardly from the lower liner portion and covering a lateral surface of the via contact.

18. The semiconductor device as claimed in claim 16, wherein the liner covers a lateral surface of the via contact, and the via contact is in direct contact with the metal gate feature.

19. The semiconductor device as claimed in claim 16, wherein the liner and the via contact are made of a same material.

20. The semiconductor device as claimed in claim 16, wherein an upper surface of the metal gate feature has a size ranging from 1 nm to 15 nm.
